(19) United States
(12) Patent Application Publication
(10) Pub. No.: US 2025/0311223 A1
(43) Pub. Date: Oct. 2, 2025

(54) SEMICONDUCTOR MEMORY DEVICE

(71) Applicant: SAMSUNG ELECTRONICS CO., LTD., Suwon-si (KR)

(72) Inventors: Hyunhaeng Heo, Suwon-si (KR); Minsu Kim, Suwon-si (KR); Hongsoo Jeon, Suwon-si (KR)

(21) Appl. No.: 19/024,976

(22) Filed: Jan. 16, 2025

(30) Foreign Application Priority Data
Apr. 2, 2024 (KR) 10-2024-0044967

(51) Int. Cl. H10B 43/40; G11C 16/24; H10B 41/41

(52) U.S. Cl. CPC H10B 43/40; G11C 16/24; H10B 41/41

(57) ABSTRACT

A semiconductor memory device includes a substrate comprising a plurality of page buffer regions disposed in a first direction, circuits, respectively provided on the page buffer regions, an interlayer insulating layer disposed above the substrate to cover the circuits, and a plurality of interconnections disposed directly on the interlayer insulating layer and respectively connected to the circuits. The plurality of interconnections may include circuit interconnections, respectively connected to the circuits, and at least one common interconnection provided on the circuits. The common interconnection may be connected to at least two of the circuits.

### CROSS-REFERENCE TO RELATED APPLICATION(S)

This U.S. non-provisional application claims priority under 35 USC § 119 to Korean Patent Application No. 10-2024-0044967, filed on Apr. 2, 2024, in the Korean Intellectual Property Office, the disclosure of which is herein incorporated by reference in its entirety.

### BACKGROUND

Example implementations relate to semiconductor memory devices, and more particularly to, a semiconductor memory device including page buffers.

With the increasing multifunctionality of information and communications devices in recent years, there is growing demand for higher-capacity and highly integrated memory devices. As memory cell sizes are reduced to achieve higher integration density, operation circuits and interconnection structures included in memory devices for operations and electrical connections of the memory device are becoming more complex. Accordingly, there is demand for memory devices with higher integration density and improved electrical characteristics.

A memory device may include page buffers for storing data in or outputting data from memory cells. The page buffers may include semiconductor devices such as transistors. Due to the increasing demand for smaller page buffer sizes driven by the integration of memory devices and the development of process technology, the size of semiconductor devices included in page buffer circuits may decrease, and the layout of interconnections connected to the semiconductor devices may become more complex with a plurality of layers. Accordingly, there is a need to optimize the layout of the interconnections without degradation of performance of the memory devices.

### SUMMARY

Example implementations provide a semiconductor memory device with a simpler manufacturing process and low costs, which is achieved by changing a layout of interconnections in page buffers.

According to some implementations, a semiconductor memory device includes a substrate comprising a plurality of page buffer regions disposed in a first direction, circuits, respectively provided on the page buffer regions, an interlayer insulating layer disposed above the substrate to cover the circuits, and a plurality of interconnections disposed directly on the interlayer insulating layer and respectively connected to the circuits. The plurality of interconnections may include circuit interconnections, respectively connected to the circuits, and at least one common interconnection provided on the circuits. The common interconnection may be connected to at least two of the circuits.

The circuit interconnections and the common interconnection may be disposed in the same layer on the substrate.

Each of the circuits may include a plurality of transistors disposed in each page buffer region in a second direction intersecting the first direction, and the transistors of the circuits may include the transistors disposed in a row in the first direction and including a common gate pattern. The common interconnection may be connected to the common gate pattern.

The common gate pattern may be provided in plural.

The common interconnection may be provided in plural.

The common gate patterns may be connected to the common interconnections through contacts, respectively, and the contacts may be disposed in at least one of the page buffer regions.

Each of the circuits may include a plurality of transistors disposed in each page buffer region in the second direction intersecting the first direction, each of the transistors may include a gate pattern and an active pattern, and the circuit interconnections may overlap the active patterns.

The common interconnection may not overlap the active patterns.

The semiconductor memory device may further include a plurality of connection pads provided between the circuits and the plurality of interconnections to connect the circuits and the plurality of interconnections.

A portion of the connection pads may overlap the interconnections and the active patterns in plan view.

A portion of the connection pads may overlap the interconnections and the gate patterns or common gate patterns in plan view.

The plurality of connection pads may be connected to the circuitry and the common interconnection through first contacts and may be connected to the transistors through second contacts.

One or some of the first contacts may not overlap the active pattern.

The interlayer insulating layer may include a first interlayer insulating layer provided on the circuits and a second interlayer insulating layer provided on the first interlayer insulating layer, and the plurality of connection pads may be provided on the first interlayer insulating layer.

According to some implementations, a semiconductor memory device includes a substrate comprising a plurality of page buffer regions disposed in a first direction, circuits, respectively provided on the page buffer regions, an interlayer insulating layer disposed above the substrate to cover the circuits, and a plurality of interconnections disposed directly on the interlayer insulating layer and respectively connected to the circuits. The plurality of interconnections may include circuit interconnections, respectively connected to the circuits, at least one common interconnection provided on the circuits and connected to all of the circuits, and a plurality of connection pads provided between the circuits and the plurality of interconnections to connect the circuits and the plurality of interconnections.

The circuit interconnections and the common interconnection may be disposed in a same layer on the substrate.

A portion of the connection pads may overlap the interconnections and the active patterns in plan view, and the plurality of connection pads may connected to the circuitry and the common interconnection through first contacts and may be connected to the interconnections through second contacts.

According to some implementations, a semiconductor memory device includes a first structure, including page buffers, and a second structure including memory cells connected to the page buffers and stacked on the first structure. The page buffers may include a substrate comprising a plurality of page buffer regions disposed in a first direction, circuits, respectively provided on the page buffer regions, an interlayer insulating layer disposed above the substrate to cover the circuits, and a plurality of interconnections disposed directly on the interlayer insulating layer and respectively connected to the circuits. The plurality of interconnections may include circuit interconnections, respectively connected to the circuits, and at least one common interconnection provided on the circuits and connected to all of the circuits.

The first structure may include first bonding pads exposed on an upper surface of the first structure, and the second structure may include second bonding pads exposed on a lower surface of the second structure. The first and second bonding pads may be bonded to each other.

The second structure may include a memory cell region, in which the memory cells are provided, and a through-interconnection region adjacent to the memory cell region, and the page buffers and the memory cells may be connected through a through-via penetrating through the first structure in the through-interconnection region.

### BRIEF DESCRIPTION OF DRAWINGS

FIG. 1 is a block diagram of a semiconductor memory device according to some implementations.

FIG. 2 is a circuit diagram illustrating a memory block BLK and page buffers PB according to example implementations.

FIG. 3 is a circuit diagram of one of the page buffers.

FIG. 4A is a plan view illustrating a portion of the page buffers of FIG. 3, and FIG. 4B is a cross-sectional view taken along line A-A′ of FIG. 4A.

FIG. 5 is a plan view illustrating a portion of the page buffers according to some implementations and illustrating that three common interconnections are provided.

FIGS. 6A and 6B are plan views illustrating a portion of the page buffers according to some implementations.

FIG. 7 is a plan view illustrating page buffers according to some implementations.

FIG. 8A is a plan view illustrating a portion of the page buffers according to some implementations, and FIG. 8B is a cross-sectional view taken along line B-B′ of FIG. 8A.

FIG. 9 is a conceptual cross-sectional view illustrating a semiconductor memory device according to some implementations.

FIG. 10 is a conceptual cross-sectional view illustrating a semiconductor memory device according to some implementations.

### DETAILED DESCRIPTION

The present disclosure may be modified in various ways and may have various implementations, among which specific implementations will be described in detail with reference to the accompanying drawings. However, it should be understood that the description of the specific implementations of the present disclosure is not intended to limit the present disclosure to a particular mode of practice, and that the present disclosure is to cover all modifications, equivalents, and substitutes included in the spirit and technical scope of the present disclosure.

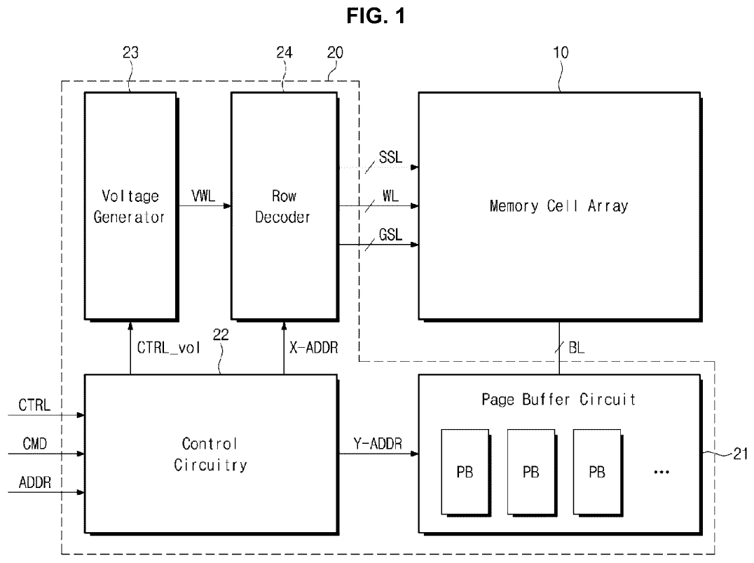

FIG. 1 is a block diagram of a semiconductor memory device according to some implementations.

Referring to FIG. 1, the semiconductor memory device may include a memory cell array 10 and peripheral circuitry 20. The peripheral circuitry 20 may include a page buffer circuit 21, control circuitry 22, a voltage generator 23, and a row decoder 24. The peripheral circuitry 20 may further include a data input/output circuit, an input/output interface, or the like.

The memory cell array 10 may be connected to the page buffer circuit 21 through bitlines BL and may be connected to the row decoder 24 through wordlines WL, string select lines SSL, and ground select lines GSL. The memory cell array 10 may include a plurality of memory cells. The memory cells may be, for example, flash memory cells. Hereinafter, example implementations will be described with respect to a case in which the plurality of memory cells are NAND flash memory cells. However, example implementations are not limited thereto. In some implementations, the plurality of memory cells may be resistive memory cells such as resistive RAM (ReRAM) cells, phase change RAM (PRAM) cells, or magnetic RAM (MRAM) cells.

In some implementations, the memory cell array may include a plurality of memory blocks. In some implementations, each memory block may include a three-dimensional (3D) memory cell array, the 3D memory cell array may include a plurality of memory cell strings, and each memory cell string may include memory cells connected to wordlines stacked vertically on a substrate. For example, the memory cells of each memory cell string of the 3D memory cell array 10 may be provided on a plurality of different levels, and each wordline may be commonly connected to memory cells disposed on the same level. Bitlines of the 3D memory cell array may be connected to channel structures, vertically penetrating through wordlines. However, example implementations are not limited thereto. In some implementations, the memory cell array 10 may include a two-dimensional (2D) memory cell array, and the 2D memory cell array may include a plurality of memory cell strings, two-dimensionally arranged in row and column directions.

The control circuitry 22 may output various control signals, such as a voltage control signal CTRL_vol, a row address X-ADDR, and a column address Y-ADDR to program data in the memory cell array 10, read data from the memory cell array 10, or erase data stored in the memory cell array 10, based on a command CMD, an address ADDR, and a control signal CTRL. Accordingly, the control circuitry 22 may control the overall operation of the semiconductor memory device.

The voltage generator 23 may generate various types of voltages for performing program, read, and erase operations on the memory cell array 10 based on the voltage control signal CTRL_vol. For example, the voltage generator 23 may generate wordline voltages VWL, such as a program voltage, a read voltage, a pass voltage, an erase verify voltage, or a program verify voltage. The voltage generator 23 may further generate a string select line voltage and a ground select line voltage based on the voltage control signal CTRL_vol.

The row decoder 24 may select one of the plurality of memory blocks in response to the row address X-ADDR, select a single wordline among wordlines WL of the selected memory block, and select a single string select line SSL among a plurality of string select lines SSL. The page buffer circuit 21 may select a portion of bitlines BL in response to the column address Y-ADDR. For example, the page buffer circuit 21 may operate as a write driver or a sense amplifier depending on operation mode. The page buffer circuit 21 may include a plurality of page buffers PB, respectively connected to a plurality of bitlines BL.

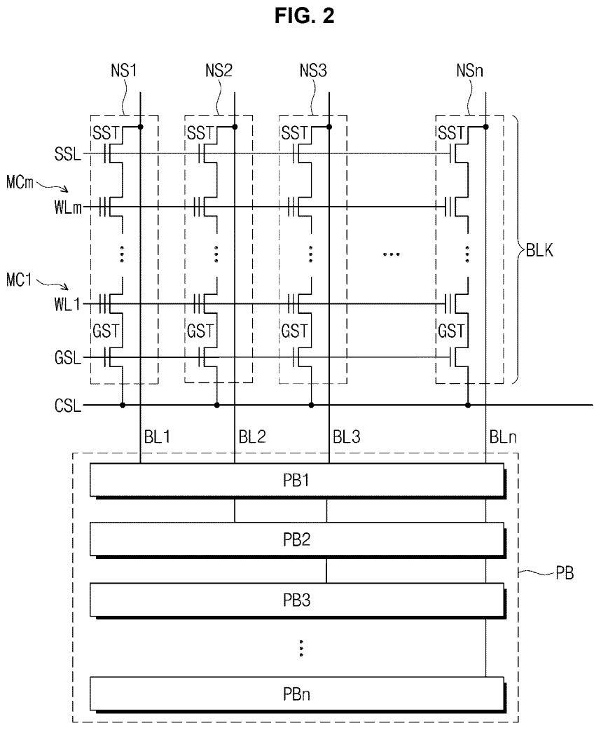

FIG. 2 is a circuit diagram illustrating a memory block BLK and page buffers PB according to example implementations. To aid understanding, FIG. 2 illustrates memory cell strings in a two-dimensional configuration.

A memory block BLK may include a plurality of memory cell strings (for example, first to nth memory cell strings NS1 to NSn). Each of the plurality of memory cell strings NS1 to NSn may include a plurality of memory cells MC1, MC2 to MCm, a string select transistor SST, and a ground select transistor GST.

In each of the memory cell strings NS1 to NSn, the ground select transistor GST, the plurality of memory cells MC1, MC2 to MCm, and the string select transistor SST may be disposed in series in a vertical direction. The plurality of memory cells MC1, MC2 to MCm may store data. A plurality of wordlines WL1, WL2 to WLm may be included in each of the memory cells MC1, MC2 to MCm and may control the corresponding memory cells MC1, MC2 to MCm, respectively. The number of memory cells MC1, MC2 to MCm may be appropriately selected depending on the capacity of the semiconductor device.

A bitline BL1, BL2, . . . , or BLn may be connected to a drain of a string select transistor SST of memory cell strings NS1 to NSn disposed in first to nth columns of a memory block BLK. In addition, a common source line CSL may be connected to a source of a ground select transistor GST of each of the memory cell strings NS1 to NSn.

A wordline (for example, WL1) may be commonly connected to gate electrodes of memory cells disposed in the same layer of the plurality of memory cell strings NS1 to NSn (for example, memory cells disposed in the same layer as the memory cell MC1). Data may be programmed in, read from, or erased from the plurality of memory cells MC1, MC2 to MCm−1, and MCm based on driving states of the wordlines WL1, WL2 to WLm−1, and WLm.

In each of the memory cell strings NS1 to NSn, the string select transistor SST may be disposed between a bitline (for example, BL1) and an uppermost memory cell MCm. In the memory block BLK, each string select transistor SST may control data transmission between the corresponding bitline BL1, BL2, . . . , or BLn and the plurality of memory cells MC1, MC2 to MCm−1, MCm due to a string select line SSL connected to a gate electrode of each string select transistor SST.

A ground select transistor GST may be disposed between a lowermost memory cell MC1 and the common source line CSL. In the memory cell array 10, each ground select transistor GST may control data transmission between the plurality of memory cells MC1, MC2 to MCm−1, and MCm and the common source line CSL due to a ground select line GSL connected to a gate electrode of each ground select transistor SST.

The memory cell strings NS1 to NSn may be connected to the page buffers PB1 to PBn through bitlines, respectively. For example, the first to nth memory cell strings NS1 to NSn may be connected to the first to nth page buffers PB1 to PBn through bitlines, respectively. The first page buffer PB1 may be connected to the first memory cell string NS1 through the first bitline BL1, the second page buffer PB2 may be connected to the second memory cell string NS2 through the second bitline BL2, and the nth page buffer PBn may be connected to the nth memory cell string NSn through the nth bitline BLn.

As described above, the semiconductor memory device according to the present embodiment may include a plurality of memory cells and a plurality of page buffers connected to the memory cells through a plurality of bitlines.

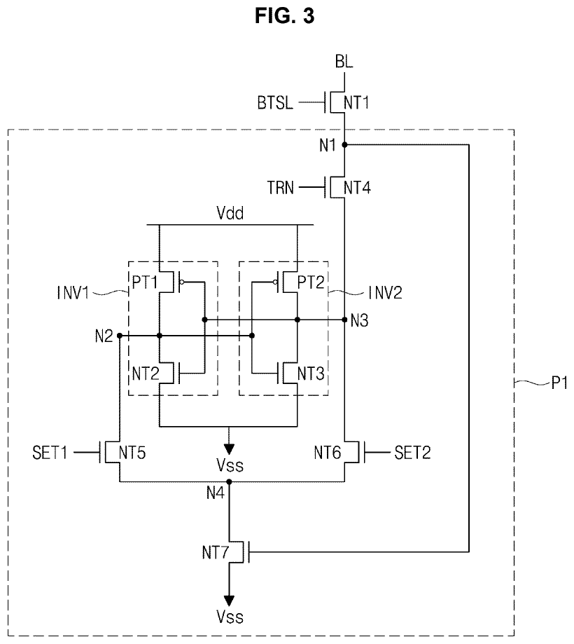

FIG. 3 is a circuit diagram of one of the page buffers PB.

Referring to FIG. 3, each page buffer PB may include a plurality of transistors. In some implementations, the plurality of transistors of each page buffer may include first and second PMOS transistors PT1 and PT2 and first to seventh NMOS transistors NT1, NT2 to NT7. The plurality of transistors may constitute a first sensing circuit, a latch, and a second sensing circuit.

The first sensing circuit may include a first NMOS transistor NT1 connected between a bitline BL and a first node N1 corresponding to a sensing node. The first NMOS transistor NT1 may connect the bitline BL and the first node N1 in response to a bitline select signal BTSL.

The latch may include a first and second PMOS transistor PT1 and PT2 and a second to sixth NMOS transistor NT2, NT3 to NT6. The first PMOS transistor PT1 and the second NMOS transistor NT2 may be connected in series between the power supply voltage Vdd and the ground voltage Vss, and a gate of the first PMOS transistor PT1 may be connected to a gate of the second NMOS transistor NT2. Accordingly, the first PMOS transistor PT1 and the second NMOS transistor NT2 may constitute a first inverter INV1. The second PMOS transistor PT2 and the third NMOS transistor NT3 may be connected in series between the power supply voltage Vdd and the ground voltage Vss, and a gate of the second PMOS transistor PT2 may be connected to a gate of the third NMOS transistor NT3. Accordingly, the second PMOS transistor PT2 and the third NMOS transistor NT3 may constitute a second inverter INV2. The first inverter INV1 and the second inverter INV2 may be connected in reverse-parallel between a second node N2 and a third node N3 to form a latch structure. The second node N2 may retain non-inverted data of the latch, and the third node N3 may retain inverted data of the latch. The fourth NMOS transistor NT4 may be connected between the first node N1 and the third node N3 and may change a potential of the first node N1 corresponding to a value of data stored in the third node N3 in response to a trans signal TRN. The fifth NMOS transistor NT5 may be connected between the second node N2 and a fourth node N4 and may connect the second node N2 and the fourth node N4 in response to a first control signal SET1. The sixth NMOS transistor NT6 may be connected between the third node N3 and the fourth node N4 and may connect the third node N3 and the fourth node N4 in response to a second control signal SET2.

The second sensing circuit may include a seventh NMOS transistor NT7. The seventh NMOS transistor NT7 may be connected between the fourth node N4 and the ground voltage Vss and may be turned on based on a potential of a sensing node, for example, the first node N1 to transmit the ground voltage Vss to the fourth node N4.

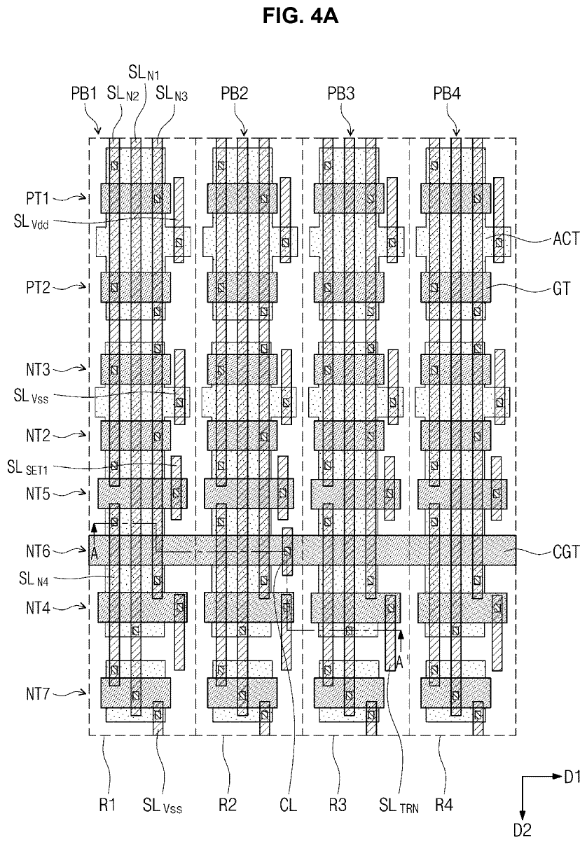

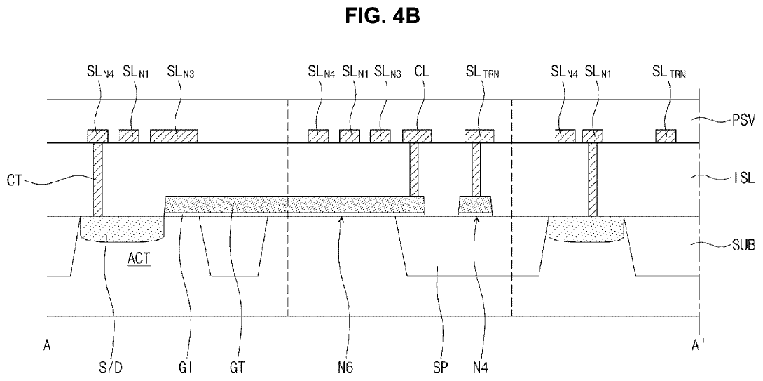

FIG. 4A is a plan view illustrating a portion corresponding to P1 of FIG. 3, and FIG. 4B is a cross-sectional view taken along line A-A′ of FIG. 4A. In some implementations, portions of four adjacent page buffers are illustrated for ease of description. However, example implementations are not limited thereto, and the number of page buffers may be changed in various ways.

Referring to FIGS. 4A and 4B, page buffers PB according to example implementations may include a substrate SUB including a plurality of page buffer regions, circuits respectively provided on the page buffer regions, an interlayer insulating layer ISL disposed on the substrate SUB to cover the circuits, and a plurality of interconnections disposed directly on the interlayer insulating layer ISL and respectively connected to the circuits.

The substrate SUB may be provided to form page buffers PB (PB1, PB2 to PB4) thereon and may include a silicon substrate, a germanium substrate, a silicon-germanium substrate, an II-VI group compound semiconductor substrate, a III-V group compound semiconductor substrate, or a silicon-on-insulator (SOI) substrate.

The page buffer regions may be disposed in a first direction D1, and the page buffers PB may be provided on the page buffer regions, respectively. For example, the page buffer regions include first to fourth page buffer regions R1, R2, R3, and R4 disposed in the first direction D1, and first to fourth page buffers PB1, PB2, PB3, and PB4 may be provided on the first to fourth page buffer regions R1, R2, R3, and R4, respectively. Hereinafter, four page buffer regions will be described as an example.

Circuits including transistors may be provided on the first to fourth page buffer regions R1, R2, R3, and R4, respectively. Each of the circuits may include a plurality of transistors disposed on a page buffer region in a second direction D2 intersecting the first direction D1. For example, the circuitry of the first page buffer PB1 may include a plurality of transistors disposed on the first page buffer region R1 in the second direction D2, and the second page buffer PB2 may include a plurality of transistors disposed on the first page buffer region R1 in the second direction D2.

In some implementations, transistors of each circuitry may include the first and second PMOS transistors PT1 and PT2 and the first to seventh NMOS transistors NT1, NT2 to NT7 of FIG. 3. FIG. 4A illustrates the first and second PMOS transistors PT1 and PT2 and the second to seventh NMOS transistors NT2, NT3 to NT7, among transistors of each circuit. A bitline BL may be connected to the first NMOS transistor NT1 that is not illustrated in FIG. 4Am and may be connected to one source/drain region of the fourth NMOS transistor NT4 through the first NMOS transistor NT1.

Transistors of each circuit may be disposed in a single column in the second direction D2. For example, the first PMOS transistor PT1, the second PMOS transistor PT2, the third NMOS transistor NT3, the second NMOS transistor NT2, the fifth NMOS transistor NT5, the sixth NMOS transistor NT6, the fourth NMOS transistor NT4, and the seventh NMOS transistor NT7 may be sequentially provided in the second direction D2. In some implementations, transistors on each of the page buffer regions disposed in the first region R1 are sequentially arranged, so that transistors constituting page buffers PB may be disposed in a matrix. Transistors of each page buffer PB, performing the same function, may be disposed in the row direction (for example, the first direction D1). For example, first PMOS transistors PT1 of each page buffer PB may be disposed in a first row, and second PMOS transistors PT2 of each page buffer PB may be disposed in a second row.

Each transistor may include an active pattern ACT and a gate pattern GT. The active pattern ACT may be a portion of the substrate SUB defined by a device isolation pattern SP. The gate pattern GT may be provided on the active pattern ACT with a gate insulating layer GI interposed therebetween. The active pattern ACT may include a source/drain region S/D of each transistor. The active pattern ACT may be doped with impurities of first conductivity type, or second conductivity type opposite to the first conductivity type, into the substrate SUB. The source/drain region S/D may be doped with impurities of a conductivity type opposite to a conductivity type of the corresponding active pattern ACT. For example, when the active pattern ACT may be doped with impurities of the first conductivity type, the source/drain region S/D formed within the active pattern ACT may be doped with impurities of the second conductivity type.

In the transistors constituting each page buffer PB, the gate patterns GT may have a shape extending in the first direction D1 and may be disposed in the second direction D2. The active patterns ACT may also be disposed in the second direction D2. The active patterns ACT within a single page buffer PB may be spaced apart from active patterns ACT within an adjacent page buffer PB, rather than connected thereto, in the first direction D1.

In example implementations, active patterns ACT (or source/drain regions S/D) provided between two adjacent gate patterns GT may be connected to each other or spaced apart from each other. For example, active patterns ACT (or source/drain regions S/D) between the second PMOS transistor PT2 and the third NMOS transistor NT3 may be spaced apart from each other. In addition, active patterns ACT (or source/drain regions S/D) between the fourth NMOS transistor NT4 and the seventh NMOS transistor NT7 may be spaced apart from each other.

In example implementations, at least one of the gate patterns GT of the transistors provided in a page buffer PB may extend in the row direction (for example, the first direction D1) to be connected to a corresponding transistor, among the transistors provided in another page buffer PB adjacent to the first page buffer PB in the first direction D1. For example, a sixth NMOS transistor NT6 of the first page buffer PB1 and a sixth NMOS transistor NT6 of the second page buffer PB2 adjacent to the first page buffer PB1 may share a gate pattern GT extending in the first direction D1 to intersect the first page buffer region R1 and the second page buffer region R2. In addition, gate patterns of the sixth NMOS transistors NT6 of the third and fourth page buffers PB3 and PB4 may extend to be connected to gate patterns GT of the sixth NMOS transistors NT6 of the first and second page buffers PB1 and PB2. For example, the sixth NMOS transistors NT6 of the first to fourth page buffers PB1, PB2, PB3, and PB4 may share a gate pattern GT extending in the first direction D1 to intersect the first to fourth page buffer regions R1, R2, R3, and R4. Such a gate pattern GT commonly shared by two adjacent transistors may be referred to as a common gate pattern CGT, and the common gate pattern CGT may be commonly shared by transistors of a plurality of page buffers PB disposed in the first direction D1. For example, as illustrated, in the first to fourth page buffers PB1, PB2, PB3, and PB4, common gate patterns CGT may have an elongated shape extending in the first direction D1 to correspond to all of the first to fourth page buffers PB1, PB2, PB3, and PB4.

An interlayer insulating layer ISL may be provided on the substrate SUB on which the circuitry is formed.

A plurality of interconnections may be provided on the interlayer insulating layer ISL. The plurality of interconnections may be provided to apply various signals (for example, a control signal, a trans signal, or the like), a power supply voltage Vdd, and ground voltage Vss to transistors of the page buffers PB.

The plurality of interconnections may include circuit interconnections SL_{N1}, SL_{N2}, SL_{N3}, SL_{N4}, SL_{Vdd}, SL_{Vss}, SL_{SET1}, and SL_{TRN} (hereinafter referred to as SL), respectively connected to the circuits, and a common interconnection CL connected to all circuits.

The plurality of interconnections, for example, the circuit interconnections SL and the common interconnection CL, may be provided directly on the interlayer insulating layer. For example, lower surfaces of the circuit interconnections SL and the common interconnection CL may be in contact with an upper surface of the interlayer insulating layer. The circuit interconnections SL and the common interconnection CL may be disposed on substantially the same level from the substrate SUB. For example, the circuit interconnections SL and the common interconnection CL may be disposed within the same layer on the interlayer insulating layer. The terms “same level” or “same layer” may refer to a single layer formed in the same process, even if it is not at the same height, including layers disposed at the same height from a substrate surface. In some implementations, a conductive layer may be formed on the interlayer insulating layer. The conductive layer may be patterned to form circuit interconnections SL and a common interconnection CL, but example implementations are not limited thereto. In some implementations, the plurality of interconnections, for example, the circuit interconnections SL and the common interconnection CL, may be spaced apart from each other in a lateral direction when viewed in cross-section.

A passivation layer PSV may be provided on the interlayer insulating layer ISL on which the interconnections may be formed.

The circuit interconnections SL may be provided for each page buffer PB and connected to the circuitry of each page buffer PB. The circuit interconnections SL may include interconnections corresponding to each node and interconnections for power/ground to provide various signals. In some implementations, the circuit interconnections SL may include first to fourth signal lines SL_{N1}, SL_{N2}, SL_{N3}, and SL_{N4}, respectively corresponding to the first to fourth nodes N1, N2, N3, and N4, a fifth signal line SL_{Vdd} applied with a power supply voltage Vdd, and a sixth signal line SL_{Vss} applied with a ground voltage Vss. In addition, the circuit interconnections SL may include a seventh signal line SLSET1, applied with a first control signal SET1 (see FIG. 3), and an eighth signal line SLTRN applied with a trans signal TRN (see FIG. 3). The first node N1 may correspond to a sensing node (see FIG. 3), a second node N2 may correspond to a non-inverting node (see FIG. 3), the third node N3 may correspond to an inverting node (see FIG. 3), and the fourth node N4 may correspond to a common node (see FIG. 3).

In some implementations, the circuit interconnections SL may overlap the active patterns ACT within each page buffer PB. At least a portion of the circuit interconnection SL may overlap the active patterns ACT. For example, the circuit interconnections SL may be connected to corresponding terminals (for example, corresponding source/drain regions S/D and corresponding gate patterns through contacts CT), and all contacts CT connected to the circuit interconnections SL may vertically overlap the active patterns ACT.

The circuit interconnections SL may be repeatedly disposed for each page buffer region. For example, the first to eighth signal lines SL_{N1}, SL_{N2}, SL_{N3}, SL_{N4}, SL_{Vdd}, SL_{Vss}, SL_{SET1}, and SL_{TRN} may be repeatedly disposed for each page buffer region. An order, in which the circuit interconnections SL are disposed, may be the same for each page buffer PB. For example, in each of the first to fourth page buffers PB1, PB2, PB3, and PB4, the second signal line SL_{N2}, the first signal line SL_{N1}, and the third signal line SL_{N3} may be disposed in the order listed on the first PMOS transistor PT1. However, the order of the circuit interconnections SL may be not limited thereto.

In some implementations, an order of the circuit interconnections SL of at least one of the page buffers PB may be different from an order of the circuit interconnections SL of at least another of the page buffers PB. For example, the second signal line SL_{N2}, the first signal line SL_{N1}, and the third signal line SL_{N3} may be disposed in the order listed on the first PMOS transistor PT1 of the first page buffer PB1, and the first signal line SL_{N1}, the second signal line SL_{N2}, and the third signal line SL_{N3} may be disposed in the order listed on the first PMOS transistor PT1 of the second page buffer PB2.

In addition, the circuit interconnections SL within each page buffer region may be repeated or symmetrical at specific intervals. For example, the circuit interconnections SL of the first page buffer PB1 and the circuit interconnections SL of the second page buffer PB2 may have a symmetrical shape along an imaginary line between the first page buffer PB1 and the second page buffer PB2. Alternatively, the first and second page buffers PB1 and PB2 may have circuit interconnections SL disposed in the same order, and the third and fourth page buffers PB3 and PB4 may have circuit interconnections SL disposed in an order, different from an order in which the first and second page buffers PB1 and PB2 are disposed. Additionally, the circuit interconnections SL of the first and second page buffers PB1 and PB2 and the third and fourth page buffers PB3 and PB4 may be repeated two or more times in the first direction D1. The order and repetition of the circuit interconnections SL may vary according to example implementations. The order and repetition of the circuit interconnections SL may ensure a sufficient space when the common interconnection CL is formed.

The common interconnection CL may be connected to the common gate pattern CGT and may be connected to at least one of the transistors constituting a page buffer PB. Each common interconnection CL may be provided in one of the page buffers PB to be connected to a corresponding common gate pattern CGT. For example, the common interconnection CL may be connected to a common gate pattern CGT shared by the sixth NMOS transistors NT6. The common interconnection CL may be provided in one page buffer PB but may not be provided to the remaining page buffers PB. The common interconnection CL may be provided to only a portion of the page buffers PB, for example, only one page buffer PB, but may be connected to all circuits through the common gate pattern CGT. For example, as illustrated in FIG. 4A, the common gate pattern CGT and common interconnection CL may be provided only in the second page buffer PB2, and the common interconnection CL may not be provided in the first page buffer PB1, the third page buffer PB3, and the fourth page buffer PB4.

In some implementations, the common interconnection CL may not overlap the active patterns ACT. The common interconnection CL may be provided on a region between two circuits of two adjacent page buffers PB. For example, the common interconnection CL may be provided in a region between device isolation patterns SP of the two circuits. For example, the common interconnection CL may be provided between the first page buffer PB1 and the second page buffer PB2 but may be provided on either one of the first page buffer region R1 and the second page buffer region R2. Alternatively, the common interconnection CL may vertically overlap a boundary between the first page buffer region R1 and the second page buffer region R2.

The common gate pattern CGT may be shared by the plurality of page buffers PB, so that the same signal may be applied to the common gate pattern CGT of the plurality of page buffers PB via the common interconnection CL. For example, during read and write operations on memory cells, the sixth NMOS transistors NT6 connected to the common gate pattern CGT may perform the same corresponding function in the plurality of page buffers PB.

Contacts CT may be provided on the interlayer insulating layer ISL between circuitry and an interconnection to connect the circuitry and the interconnection. The contacts CT may electrically and physically connect the circuitry and the interconnection through the interlayer insulating layer ISL.

The circuit interconnections SL may be connected to the gate patterns GT and/or active patterns ACT (for example, the source/drain regions S/D of the page buffers PB) through corresponding contacts CT. At least a portion of the circuit interconnections SL may be disposed on the active patterns ACT, and the circuit interconnections SL may be connected to the circuitry through corresponding contacts CT in locations in which the circuit interconnections SL overlap the active patterns ACT.

The common interconnection CL may be connected to the common gate pattern CGT of the page buffers PB through a corresponding contact CT. The common interconnection CL may be disposed such that the entirety of, or at least a portion of, the common interconnection CL does not overlap the active patterns ACT, but may be disposed to overlap the common gate pattern CGT. The common interconnection CL may be connected to the common gate pattern CGT through a contact CT in a location in which the common interconnection CL overlaps the common gate pattern CGT.

The page buffers PB and the interconnection connected to the page buffers PB have been described as an example, and the arrangement of the transistors and interconnections constituting each page buffer PB may be different from the above description but still be within the scope of the present disclosure.

In some implementations, intervals between the circuit interconnections SL and the common interconnection CL have been illustrated as being uniform within a single page buffer PB. However, this is for ease of description, and example implementations are not limited thereto. Intervals between the circuit interconnections SL within a page buffer PB and intervals between a common interconnection CL and adjacent to the circuit interconnections SL may be the same or may be different. For two adjacent page buffers PB, a distance between the circuit interconnections SL or common interconnection CL of a buffer PB on one side and the circuit interconnections SL or common interconnection CL of a page buffer PB on the other side may be different from a distance between adjacent circuit interconnections SL and/or common interconnection CL within a single page buffer PB. For example, for two adjacent page buffers PB, a distance between the circuit interconnections SL of the page buffer PB on the one side and the circuit interconnections SL of the page buffer PB on the other side may be larger than a sufficient interval, for example, a distance between circuit interconnections SL of adjacent circuit interconnections SL within a single page buffer PB to provide the common interconnection CL between the circuit interconnections SL of the page buffers PB on the one side and the other side.

In some implementations, widths of the page buffers PB in the first direction D1 are illustrated as having the same value, but example implementations are not limited thereto. The widths of the page buffers PB in the first direction may vary depending on the arrangement of the interconnection, and a page buffer PB provided with a common interconnection CL may have a larger width and a page buffer PB provided with no common interconnection CL may have a smaller width.

According to some implementations, the number of interconnections that need to be connected to each page buffer PB may be significantly reduced. For example, if m page buffers PB are disposed and n interconnections need to be connected to a single page buffer PB, then a total of m×n interconnections are required when a common interconnection CL is not used. If one of the n interconnections that need to be connected to the single page buffer PB is used as a common interconnection CL, n−1 interconnections are provided for each of the m page buffers PB and a single common interconnection CL is connected to all of four page buffers PB, so that a total of m×(n−1)+1 interconnections are required. For example, if four interconnections need to be connected to four page buffers PB, the number of interconnections required when a common interconnection CL is not used is 16 and the number of interconnections required when a single common interconnection CL is used is 13.

As described above, according to example implementations, the number of interconnections provided for each page buffer PB may be significantly reduced using a common interconnection CL. In example implementations, the number of interconnections provided for each page buffer PB is reduced, so that a plurality of interconnections, including circuit interconnections SL and common interconnections CL, may be provided on substantially the same level. In the case in which interconnections are formed on the same level, a manufacturing process may be significantly simplified compared to the case in which interconnections are formed in a plurality of layers on different levels. This simplified manufacturing process is now described in more detail. When a common interconnection CL is not used as described in some of the example implementations, interconnections for that specific signal should be formed for each page buffer PB to provide a specific signal to each transistor. When the number of interconnections connected to each transistor is large, all of the interconnections cannot be formed on the same level (for example, a single layer) and should be formed in two or more layers. As described above, when interconnections are formed in two or more layers, the interconnections should be distributed and disposed on two or more stacked interlayer insulating layers ISL. A plurality of contacts CT may be required to connect two or more layers of interconnections to corresponding transistors, and additional transfer interconnection may also be required to connect the plurality of contacts CT and transistors. Accordingly, an additional photolithography process, or the like, may be required to form two or more layers of interconnection, resulting in increased process time and costs.

In some implementations, the number of interconnections provided for each page buffer PB may be significantly reduced using a common interconnection CL, allowing interconnections to be disposed on a minimum number of layers (for example, a single layer). In some implementations, interconnections are provided on a single layer, so that a process and costs for forming the interconnections may be reduced. In addition, interconnections connected to a page buffers PB may be formed on substantially the same level to provide a space in which other components, except for the page buffer PB, may be disposed.

In some implementations, the common gate pattern and the common interconnection may each be provided in plural.

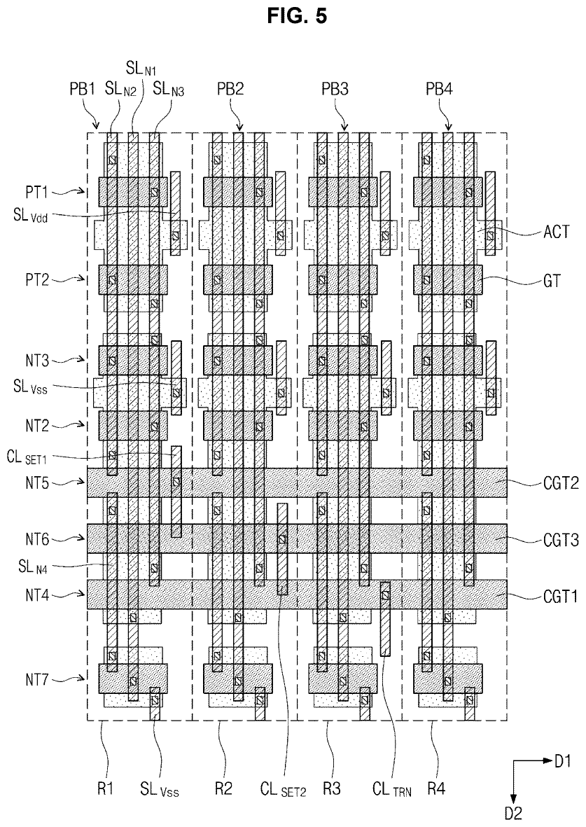

FIG. 5 is a plan view illustrating a portion of the page buffers according to some implementations and illustrating that three common interconnections are provided. In the following implementations, differences from the above-described implementations will be mainly described to avoid repetition.

Referring to FIG. 5, in example implementations, a plurality of gate patterns GT, among gate patterns GT of transistors provided in one page buffer PB, may extend in a first direction to be respectively connected to corresponding gate patterns GT of transistors provided to another page buffer PB adjacent to the one page buffer PB, thereby implementing a plurality of common gate patterns CGT1, CGT2, and CGT3 (hereinafter CGT).

For example, a fourth NMOS transistor NT4 among transistors provided in the first page buffer PB1 and a fourth NMOS transistor NT4 among transistors provided in an adjacent second page buffer PB2 may share a gate pattern GT. Similarly, a fifth NMOS transistor NT5 among the transistors provided in the first page buffer PB1 and a fifth NMOS transistor NT5 among the transistors provided in the adjacent second page buffer PB2 may share a gate pattern GT, and a sixth NMOS transistor NT6 among the transistors provided in the first page buffer PB1 and a sixth NMOS transistor NT6 among the transistors provided to the adjacent second page buffer PB2 may share a gate pattern GT. For example, the common gate pattern CGT may be provided in plural. The plurality of common gate patterns CGT may include a first common gate pattern CGT1 shared by the fourth NMOS transistors NT4 of each page buffer PB, a second common gate pattern CGT2 shared by the fifth NMOS transistors NT5 of each page buffer PB, and a third common gate pattern CGT3 shared by the sixth NMOS transistors NT6 of each page buffer PB.

The common interconnections CL may be connected to the common gate patterns CGT, respectively, and may include a first common interconnection CL_{SET1} to which a first control signal SET1 is applied, a second common interconnection CL_{SET2} to which a second control signal is applied, and a third common interconnection CL_{TRN} to which a trans signal is applied. Each of the first to third common interconnections CL_{SET1}, CL_{SET2}, and CL_{TRN} may be provided to one of the page buffers PB to be connected to corresponding common gate patterns CGT. For example, the first common interconnection CL_{SET1} may be connected to the first common gate pattern CGT1 shared by the fourth NMOS transistors NT4, the second common interconnection CL_{SET2} may be connected to the second common gate pattern CGT2 shared by the fifth NMOS transistors NT5, and the third common interconnection CL_{TRN} may be connected to the third common gate pattern CGT3 shared by the sixth NMOS transistors NT6.

The common interconnections CL may be connected to the gate patterns GT of the page buffers PB through contacts CT, respectively. Each of the common interconnections CL may be disposed such that all, or a portion, of the common interconnections CL do not overlap active patterns ACT, but may be disposed to overlap corresponding common gate patterns CGT. The common interconnections CL may be connected to the common gate patterns CGT through corresponding contacts CT in a location, in which the common interconnections CL overlap the common gate patterns CGT, respectively.

Each of the first to third common interconnections CL_{SET1}, CL_{SET2}, and CL_{TRN} may be provided in one of the first to fourth page buffers PB1, PB2, PB3, and PB4 to be connected to a corresponding one of the first to third common gate patterns CGT1, CGT2, and CGT3. The first to third common interconnections CL_{SET1}, CL_{SET2}, and CL_{TRN} may not be provided in page buffer regions, except for page buffer regions in which contacts CT, through which the first to third common interconnections CL_{SET1}, CL_{SET2}, and CL_{TRN} and the first to third common gate patterns CGT1, CGT2, and CGT3 are connected to each other, are disposed.

For example, the first common interconnection CL_{SET1} may be connected to the second common gate pattern CGT3 on the first page buffer region R1 and may be not provided on the third page buffer region R3, the second page buffer region R2, and the fourth page buffer region R4. Similarly, the second common interconnection CL_{SET2} may be connected to the third common gate pattern CGT3 on the second page buffer region R2 and may be not provided on the first, third, or fourth page buffer regions R1, R3, and R4. The third common interconnection CL_{TRN} may be connected to the first common gate pattern CGT1 on the third page buffer region R3 and may be not provided on the first page buffer region R1, the second page buffer region R2, and the fourth page buffer region R4.

According to some implementations, gate patterns GT separated and provided for each page buffer PB may be formed as common gate patterns CGT shared by a plurality of page buffers PB, and a single common interconnection CL may be connected to each common gate pattern CGT. In the present embodiment, the number of circuit interconnections SL may be significantly reduced compared to the case in which a single common gate pattern CGT and a single common interconnection CL are used.

According to some implementations, common interconnections and common gate patterns may vary within the scope of the present disclosure.

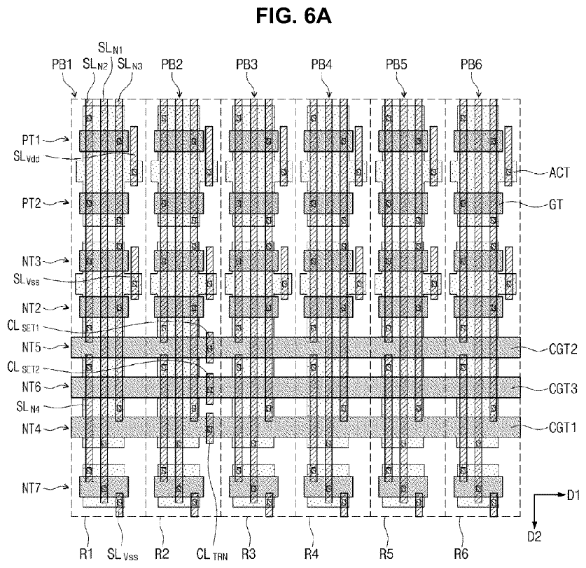

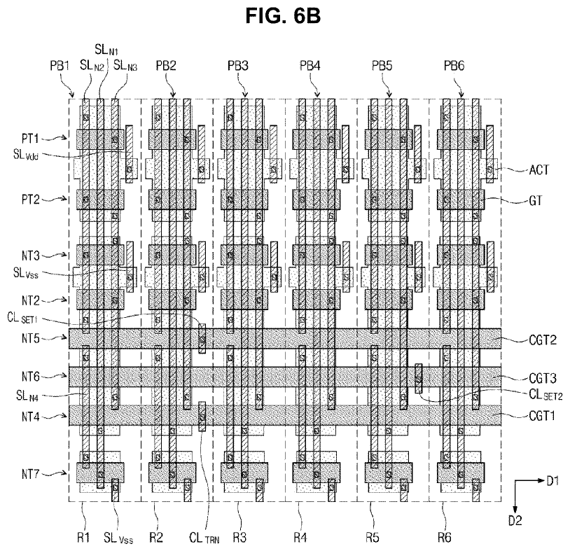

FIGS. 6A and 6B are plan views illustrating a portion of the page buffers according to implementations. In the following implementations, for ease of description, first to sixth page buffers PB1, PB2, PB3 to PB6 are illustrated as being disposed in a first direction D1.

Referring to FIG. 6A, common interconnections CL may be provided on a single page buffer region, rather than different page buffer regions. For example, first to third common interconnections CL_{SET1}, CL_{SET2}, and CL_{TRN} may be provided on a second page buffer region R2. For example, all of the first to third common interconnections CL_{SET1}, CL_{SET2}, and CL_{TRN} may be connected to first to third common gate patterns CGT1, CGT2, and CGT3 in the second page buffer region R2. Common interconnections CL may be not provided in a first page buffer region R1 and third to sixth page buffer regions R3, R4, R5, and R6.

Referring to FIG. 6B, common interconnections CL may be provided on some of the page buffer regions. For example, the second common interconnection CL_{SET2} may be provided on the fifth page buffer region R5, and each of the first common interconnection CL_{SET1} and the third common interconnection CL_{TRN} may be provided on the second page buffer region R2.

In some implementations, a common gate pattern and a common interconnection connected to the common gate pattern may be provided in plural in transistors of page buffers disposed in a first direction.

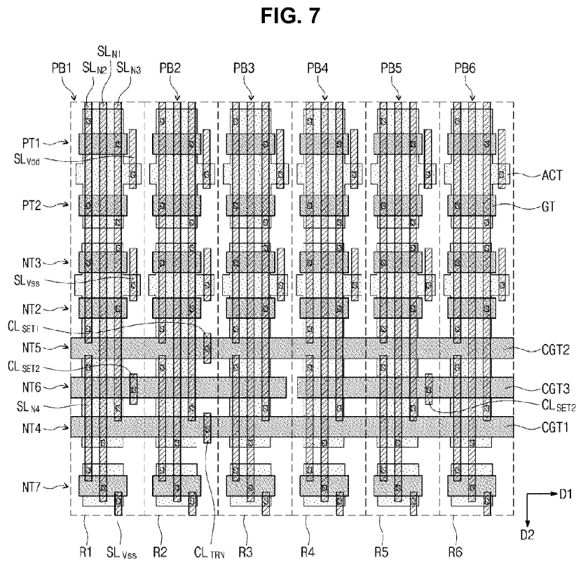

FIG. 7 is a plan view illustrating page buffers according to some implementations.

Referring to FIG. 7, a common gate pattern CGT may extend to an adjacent page buffer region in a first direction D1 and may be provided in plural.

In some implementations, fourth NMOS transistors NT4 provided in each page buffer PB may share a first common gate pattern CGT1, fifth NMOS transistors NT5 may share a second common gate pattern CGT2, and a sixth NMOS transistors NT6 may share a third common gate pattern CGT3. At least one of the first to third common gate patterns CGT1, CGT2, and CGT3 may be provided in plural. For example, as illustrated in the drawing, the third common gate pattern CGT3 may be provided in two, including a gate pattern extending from a first page buffer region R1 to a third page buffer region R3 and a gate pattern extending from a fourth page buffer region R4 to a sixth page buffer region R6.

The common interconnections CL may be provided in a corresponding number to the common gate patterns CGT to be connected to each common gate pattern CGT. For example, a first common interconnection CL_{SET1} may be connected to the second common gate pattern CGT2 shared by the fifth NMOS transistors NT5, a second common interconnection CL_{SET2} may be connected to the second common gate pattern CGT2 shared by the sixth NMOS transistors NT6, and the third common interconnection CL_{TRN} may be connected to the first common gate pattern CGT1 shared by the fourth NMOS transistors NT4. The third common gate patterns CGT3 are provided in two, so that the second common interconnection CL_{SET2} may be also provided in two and may be individually connected to each of the third common gate patterns CGT3.

In some implementations, the third common gate pattern CGT3 is illustrated as being provided in two section, but it may be provided in more than two sections. Also, when a common gate pattern CGT is provided in plural in a row, lengths of the common gate patterns CGT in the same row may be the same or may be different from each other. For example, in a row, one common gate pattern CGT may be shared across two page buffer regions and another common gate pattern CGT may be shared across four page buffer regions.

In some implementations, only the third common gate pattern CGT3 may be provided in two and each of the first and second common gate patterns CGT1 and CGT2 may be provided in one, but example implementations are not limited thereto. In some implementations, each of the first to third common gate patterns CGT1, CGT2, and CGT3 may be provided in plural.

The interconnection of the page buffers according to some implementations may be modified in various forms for connection to the circuit.

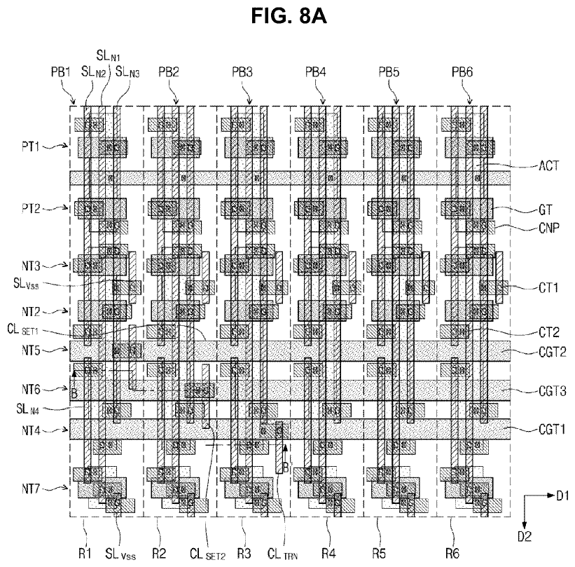

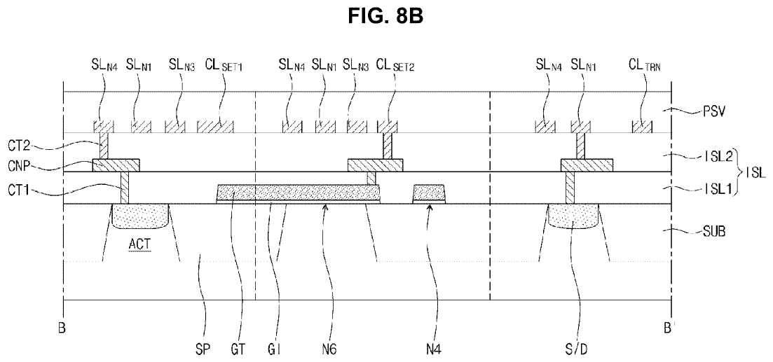

FIG. 8A is a plan view illustrating a portion of the page buffers according to some implementations, and FIG. 8B is a cross-sectional view taken along line B-B′ of FIG. 8A.

Referring to FIGS. 8A and 8B, a semiconductor memory device according to example implementations may include a substrate SUB including a plurality of page buffer regions, circuitry respectively provided on the page buffer regions, an interlayer insulating layer ISL disposed on the substrate SUB to cover the circuitry, a plurality of interconnections disposed directly on the interlayer insulating layer ISL and respectively connected to the circuitry, and connection pads CNP provided between the circuitry and the plurality of interconnections.

The connection pads CNP may be formed of a conductive material. The conductive material may include metals such as copper, tungsten, aluminum, titanium, tantalum, nickel, stainless steel, molybdenum, manganese, cobalt, tin, magnesium, rhenium, beryllium, gallium, or ruthenium, or alloys thereof. In some implementations, the connection pads CNP may include tungsten, copper, or aluminum.

The connection pads CNP may be provided to connect the circuitry and the plurality of interconnections. When components of the circuitry to be connected and the interconnections do not overlap on a plane, it may be difficult to form contacts directly connecting the components and interconnections of the circuitry. For example, when the active pattern ACT (for example, a source/drain region S/D) is connected to one of the interconnections, the active pattern ACT (for example, the source/drain region S/D) and corresponding interconnections may not overlap each other. It may be difficult to form a contact between the active pattern ACT and the corresponding interconnection. In some implementations, the connection pads CNP may be provided such that the components of the circuitry and the interconnections, which do not overlap each other in plan view, are connected through the contacts.

In some implementations, each of the connection pads CNP may connect one of the components of the circuitry (for example, the active pattern ACT or the gate pattern GT of transistors) and one of the plurality of interconnections. When the connection pad CNP connects one of the components and one of the plurality of interconnections, they may be connected in a one-to-one manner. However, example implementations are not limited thereto, and one of the components and one of the plurality of interconnections may be connected in a one-to-many manner.

In some implementations, interconnection portions and the connection pads CNP may be provided on different layers, and the connection pads CNP may be provided on layers between the substrate SUB and the interconnection portions and provided between the circuitry and the interconnection portions on the substrate SUB to connect the circuitry and the interconnection portions. Each of the connection pads CNP overlaps at least a portion of each of the corresponding components of the circuitry and the interconnections, which do not overlap each other, to connect the circuitry and the interconnections.

In some implementations, the interlayer insulating layer ISL may include a first interlayer insulating layer ISL1 provided on the substrate SUB to cover the circuitry, and a second interlayer insulating layer ISL2 disposed on the first interlayer insulating layer ISL1. The connection pads CNP may be provided on the first interlayer insulating layer ISL1, and the plurality of interconnections may be provided on the second interlayer insulating layer ISL2. First contacts CT1 may be provided on the first interlayer insulating layer ISL1 to connect circuitry and connection pads CNP corresponding to the circuitry and second contacts CT2 may be provided on the second interlayer insulating layer ISL2 to connect connection pads CNP and interconnections corresponding to the connection pads CNP.

In some implementations, the interconnections may be provided on gate patterns GT and the active patterns ACT. A portion of the interconnections may not overlap the gate patterns GT and/or the active patterns ACT. The connection pads CNP may also be provided on the gate patterns GT and the active patterns ACT. However, the connection pads CNP may be disposed to overlap interconnections that do not overlap the gate patterns GT and/or the active patterns ACT and simultaneously overlap the gate patterns GT and/or the active patterns ACT to which the interconnections should be connected.

The first contacts CT1 may be provided in a portion in which the connection pads CNP and components of the circuitry overlap each other, and the second contacts CT2 may be provided in a portion in which the connection pads CNP and the interconnections overlap each other. For example, the first contacts CT1 may be provided in a portion in which the connection pads CNP and the gate patterns GT and/or the active patterns ACT overlap each other, and the second contacts CT2 may be provided in a portion in which the connection pads CNP and the interconnections overlap each other.

For example, a fourth signal line SL_{N4} of a first page buffer region R1 may be connected to an active pattern ACT of a fifth NMOS transistor NT5 through the first contact CT1, the connection pad CNP, and the second contact CT2. A portion of the connection pad CNP may overlap a fourth signal line SL_{N4} and another portion thereof may overlap the active pattern ACT of the fifth NMOS transistor NT5. The first contact CT1 may be provided in a portion in which the connection pad CNP and the active pattern ACT of the fifth NMOS transistor NT5 overlap each other, and the second contact CT2 may be provided in a portion in which the connection pad CNP and a fourth signal line SL_{N4} overlap each other. The above structure may allow the fourth signal line SL_{N4} to be easily connected to the active pattern ACT of the fifth NMOS transistor NT5 through the connection pad CNP even when the fourth signal line SL_{N4} does not overlap the active pattern ACT of the fifth NMOS transistor NT5. For example, when widths of the gate patterns GT and the active patterns ACT provided on each page buffer region in a first direction D1 are narrow, interconnections may not be disposed within the widths of the gate patterns GT and the active patterns ACT in the first direction D1 in consideration of a width of each of the interconnections. According to some implementations, the interconnections may be easily connected to both the gate patterns GT and the active patterns ACT even when the gate patterns GT and the active patterns ACT have narrow widths.

In some implementations, the first contacts CT1 and the second contacts CT2 may be disposed adjacent to each other to the extent that the first contacts CT1 and the second contacts CT2 overlap the connection pad CNP, in plan view. In some implementations, the first and second contacts CT1 and CT2 overlapping the connection pad CNP may be disposed adjacent to each other in the first direction D1. The connection pads CNP may be provided in a shape corresponding to the arrangement of the first contact CT1 and the second contact CT2 and may have, for example, a bar shape extending in the first direction D1. However, the arrangement of the first contact CT1 and the second contact CT2 may vary depending on the shape of the connection pad CNP or the arrangement of an object to be connected. For example, the first and second contacts CT1 and CT2 overlapping the connection pad CNP may be disposed adjacent to each other in a second direction D2.

In the above-described embodiment, the first contacts CT1 and the second contacts CT2 may not overlap in plan view. However, the locations of the first contacts CT1 and the second contacts CT2 may be not limited thereto, and it will be understood that the first contacts CT1 and the corresponding second contacts CT2 may overlap with each other when the connection pads CNP and components of the circuitry overlap each other.

The page buffers according to some implementations having the above-described structure may be employed in a semiconductor memory device.

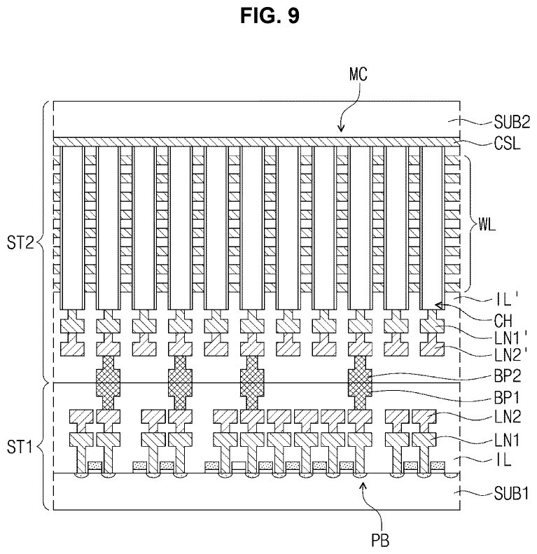

FIG. 9 is a conceptual cross-sectional view of a semiconductor memory device according to some implementations.

Referring to FIG. 9, a semiconductor memory device may include a first structure ST1 including page buffers PB and a second structure ST2 including memory cells MC connected to the page buffers PB. The second structure ST2 may be stacked on the first structure ST1.

The first structure ST and the second structure ST2 may each be fabricated in the form of a chip and may be bonded to each other. The semiconductor memory device may have a chip-to-chip (C2C) structure. The first structure ST1 and the second structure ST2 may be connected in a bonding method. For example, the bonding method may refer to a method of electrically or physically connecting bonding patterns formed on opposite surfaces of the first structure ST1 and the second structure ST2. For example, when the bonding patterns are formed of copper (Cu), the bonding method may be a Cu—Cu bonding method. For example, the bonding patterns may also be formed of aluminum (Al) or tungsten (W).

In some implementations, the semiconductor memory device may include at least one second structure ST2. Although not illustrated, for example, two or more second structures ST2 may be stacked on a single first structure ST1. However, this is only an example, and the number of the second structures ST2 is not limited thereto. In some implementations, the second structure ST2 may be flipped and connected to the first structure ST1.

The first structure ST1 may include the first substrate SUB1 and a plurality of circuit devices including a plurality of transistors formed on the first substrate SUB1.

The first substrate SUB1 may include at least one selected from the group consisting of a single-crystalline silicon layer, a polycrystalline silicon layer, a silicon-on-insulator (SOI), a silicon layer formed on a silicon-germanium (SiGe) layer, a single-crystalline silicon layer formed on an insulating layer, or a polycrystalline silicon layer formed on an insulating layer.

The plurality of circuit devices may include a row decoder, a page buffer (PB) circuit, or the like, described with reference to FIG. 1. The plurality of circuit devices may further include other circuit elements, such as a capacitor or an inductor, other than the page buffer PB.

One or more insulating layers IL and a plurality of interconnections LN1 and LN2 connecting the plurality of circuit devices may be provided on the plurality of circuit devices. For example, an insulating layer including a silicon oxide, such as a high-density plasma (HDP) oxide or a tetraethyl orthosilicate (TEOS) oxide, may be provided on the circuit devices.

The plurality of interconnections may include a first interconnection LN1, connected to each of the plurality of circuit devices such as the page buffers PB, and a second interconnection LN2 formed on the first interconnection LN1. In some implementations, the first interconnection LN1 may include interconnections connected to the circuit portion of the page buffers PB through a contact CT. In some implementations, the first interconnection LN1 may be connection pads CNP (see FIGS. 8A and 8B) connected to circuitry of the page buffers PB through the contact CT, and the second interconnection may be interconnections connected to the connection pads through the contact CT.

In the drawing, only the first interconnection LN1 and the second interconnection LN2 are illustrated and described. However, example implementations are not limited thereto, and at least one additional interconnection may be further formed on the second interconnection LN2.

The second structure ST2 may include the second substrate SUB2 and at least one memory block provided on a second substrate SUB2. The second substrate SUB2 may include at least one selected from the group consisting of a single-crystalline silicon layer, a polycrystalline silicon layer, a silicon-on-insulator (SOI), a silicon layer formed on a silicon-germanium (SiGe) layer, a single-crystalline silicon layer formed on an insulating layer, or a polycrystalline silicon layer formed on an insulating layer.

A common source line CSL may be provided on the second substrate SUB2, and a plurality of wordlines WL may be stacked on the common source line CSL in a direction, perpendicular to an upper surface of the second substrate SUB2. String select lines and ground select lines may be disposed above and below the wordlines WL, and the plurality of wordlines WL may be disposed between the string select lines and the ground select lines. A plurality of channel structures CH may be formed in each memory cell region.

The channel structure CH may extend in the direction perpendicular to the upper surface of the second substrate SUB2, to extend through the wordlines WL, the string select lines, and the ground select lines. The channel structure CH may include a data storage layer, a channel layer, and a buried insulating layer. The channel layer may be electrically connected to a first interconnection LN1′ and a second interconnection LN2′ of the second structure ST2. For example, the second interconnection LN2′ may be a bitline BL and may be connected to the channel structure CH through the first interconnection LN1′.

The wordlines WL, the string select lines, the ground select lines, or the like, may be formed of a conductive material. The conductive material may include at least one selected from the group consisting of a doped semiconductor (for example, doped silicon, or the like), a metal (for example, tungsten, copper, aluminum, or the like), a conductive metal nitride (for example, titanium nitride, tantalum nitride, or the like), or a transition metal (for example, titanium, tantalum, or the like). The wordlines WL, the string select lines, the ground select lines, or the like, may be provided on a plurality of insulating layers. Interlayer insulating layers may be formed of various materials, for example, a material including a silicon oxide, a silicon nitride, a silicon oxynitride, or the like.

In some implementations, the first structure ST1 may include a first bonding pad BP1 exposed on an upper surface of the first structure ST1, and a second structure ST2 may include a second bonding pad BP2 exposed on a lower surface of the second structure ST2. The first and second bonding pads BP1 and BP2 may be bonded to each other to connect the page buffers PB of the first structure ST1 to memory cells of the second structure ST2. For example, bitlines BL of the second structure ST2 may be connected to bonding pads of a memory cell region to be electrically connected to corresponding page buffers PB.

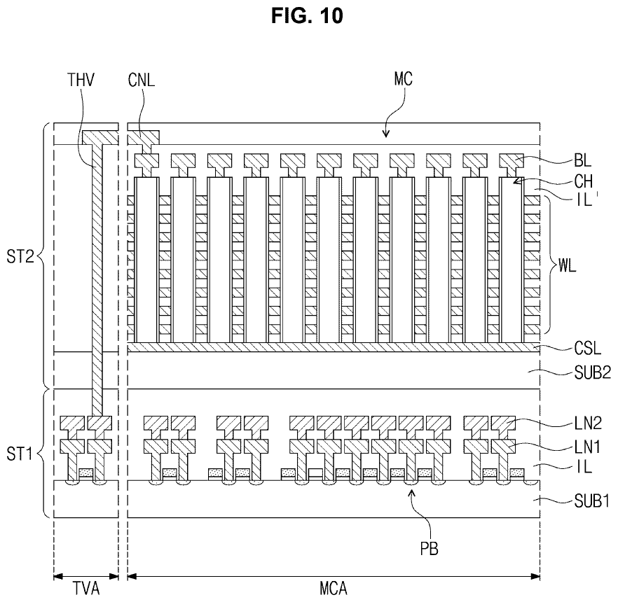

FIG. 10 is a conceptual cross-sectional view of a semiconductor memory device according to some implementations.

Referring to FIG. 10, the semiconductor memory device may have a structure in which a second structure ST2 including memory cells MC is stacked on a first structure ST1 including page buffers PB, similarly to FIG. 9.

However, in the example embodiment of FIG. 10, the second structure ST2 may not be provided in the form of a chip and may be fabricated by forming a plurality of layers including a second substrate SUB2 on the second structure ST2 after the first structure ST1 is fabricated. In some implementations, the second substrate SUB2 may include a silicon layer. The second substrate SUB2 may include a polycrystalline or single-crystalline silicon layer. In some implementations, the second substrate SUB2 may be omitted.

In the present implementations, the second structure ST2 may include a memory cell region MCA, in which memory cells MC are formed, and a through-interconnection region TVA provided on one side of the memory cell region MCA. The through-interconnection region TVA may be provided with a through-via THV extending through the second substrate SUB2 and also extending through an insulating layer IL′ of the second structure ST2, and the memory cells MC of the second structure ST2 may be connected to the page buffer PB of the first structure ST1 through the through-via THV.

Connection lines CNL may be provided above bitlines BL of the memory cell region MCA of the second structure ST2. The connection line CNL may directly extend to the through-interconnection region TVA or may indirectly extend the through-interconnection region TVA through an additional interconnection. The connection line CNL, provided on the through-interconnection region TVA, may be connected to the second interconnections LN2 of the first structure ST1 through the through-via THV. The through-via THV may be formed of a conductive material, such as a metal, a metal compound, or polysilicon. For example, a substrate through-via may include a metal such as tungsten, copper, or aluminum.

The above structure may allow the interconnections of the second structure ST2, for example, the bitlines BL, to be electrically connected to a plurality of circuit devices of the first structure ST1, for example, to the page buffers PB of the peripheral circuit region.

As described above, the page buffers according to example implementations may be employed in a semiconductor memory device including memory cells and may be used to form, for example, page buffers of the peripheral circuit region of the semiconductor memory device. According to example implementations, when page buffers are formed, the number of interconnections may be significantly reduced, and thus the number of layers, in which interconnections are formed, may be reduced. In addition, when the number of the layers, in which the interconnections are formed, are not reduced, the degree of freedom in arrangement of interconnections connected to other circuit devices, other than other page buffers, may be improved.

As set forth above, a layout of interconnections in page buffers may be modified to decrease the number of layers in which interconnections are provided, leading to a simpler manufacturing process and low costs.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been shown and described above, it will be apparent to those skilled in the art that modifications and variations could be made without departing from the scope of the present inventive concept as defined by the appended claims.

What is claimed is:

1. A semiconductor memory device comprising:
a substrate comprising a plurality of page buffer regions disposed in a first direction;
circuits, respectively provided on the page buffer regions;
an interlayer insulating layer disposed above the substrate to cover the circuits; and
a plurality of interconnections disposed directly on the interlayer insulating layer and connected to the circuits,
wherein
the plurality of interconnections comprise:
circuit interconnections, respectively connected to the circuits; and
at least one common interconnection provided on the circuits, and
the common interconnection is connected to at least two of the circuits.

2. The semiconductor memory device of claim 1, wherein
the circuit interconnections and the at least one common interconnection are disposed in the same layer on the substrate.

3. The semiconductor memory device of claim 1, wherein
each of the circuits comprises a plurality of transistors disposed in each page buffer region in a second direction intersecting the first direction, and
the plurality of transistors of the circuits comprises transistors disposed in a row in the first direction and comprising a common gate pattern, and the at least one common interconnection is connected to the common gate pattern.

4. The semiconductor memory device of claim 3, wherein
the common gate pattern is provided in plural.

5. The semiconductor memory device of claim 4, wherein
the at least one common interconnection is provided in plural.

6. The semiconductor memory device of claim 4, wherein
the common gate patterns are connected to the at least one common interconnection through contacts, respectively, and
the contacts are disposed in at least one of the page buffer regions.

7. The semiconductor memory device of claim 1, wherein
each of the circuits comprises a plurality of transistors disposed in each page buffer region in a second direction intersecting the first direction,
each of the plurality of transistors comprises a gate pattern and an active pattern, and
the circuit interconnections overlap the active patterns.

8. The semiconductor memory device of claim 7, wherein
the at least one common interconnection does not overlap the active patterns.

9. The semiconductor memory device of claim 7, further comprising:
a plurality of connection pads provided between the circuits and the plurality of interconnections to connect the circuits and the plurality of interconnections.

10. The semiconductor memory device of claim 9, wherein
a portion of the plurality of connection pads overlaps the interconnections and the active patterns in plan view.

11. The semiconductor memory device of claim 9, wherein
a portion of the plurality of connection pads overlaps the interconnections and the gate patterns or common gate patterns in plan view.

12. The semiconductor memory device of claim 9, wherein
the plurality of connection pads are connected to the circuitry and the common interconnection through first contacts, and are connected to the transistors through second contacts.

13. The semiconductor memory device of claim 12, wherein
at least some of the first contacts do not overlap the active pattern.

14. The semiconductor memory device of claim 12, wherein
the interlayer insulating layer comprises a first interlayer insulating layer provided on the circuits and a second interlayer insulating layer provided on the first interlayer insulating layer, and the plurality of connection pads are provided on the first interlayer insulating layer.

15. A semiconductor memory device comprising:
a substrate comprising a plurality of page buffer regions disposed in a first direction;
circuits, respectively provided on the page buffer regions;
an interlayer insulating layer disposed above the substrate to cover the circuits; and
a plurality of interconnections disposed directly on the interlayer insulating layer and respectively connected to the circuits,
wherein
the plurality of interconnections comprise:
circuit interconnections, respectively connected to the circuits;
at least one common interconnection provided on the circuits and connected to a plurality of the circuits; and
a plurality of connection pads provided between the circuits and the plurality of interconnections to connect the circuits with the plurality of interconnections.

16. The semiconductor memory device of claim 15, wherein
the circuit interconnections and the at least one common interconnection are disposed in a same layer on the substrate.

17. The semiconductor memory device of claim 15, wherein
a portion of the connection pads overlaps the interconnections and active patterns in plan view, and
the plurality of connection pads are connected to the circuits and the at least one common interconnection through first contacts, and are connected to the interconnections through second contacts.

18. A semiconductor memory device comprising:
a first structure comprising page buffers; and
a second structure comprising memory cells connected to the page buffers and stacked on the first structure,
wherein
the page buffers comprise:
a substrate comprising a plurality of page buffer regions disposed in a first direction;
circuits, respectively provided on the page buffer regions;
an interlayer insulating layer disposed above the substrate to cover the circuits; and
a plurality of interconnections disposed directly on the interlayer insulating layer and respectively connected to the circuits, and
the plurality of interconnections comprise:
circuit interconnections, respectively connected to the circuits; and
at least one common interconnection provided on the circuits and connected to a plurality of the circuits.

19. The semiconductor memory device of claim 18, wherein
the first structure comprises first bonding pads exposed on an upper surface of the first structure and the second structure comprises second bonding pads exposed on a lower surface of the second structure, and the first and second bonding pads are bonded to each other.

20. The semiconductor memory device of claim 18, wherein
the second structure comprises a memory cell region, in which the memory cells are provided, and a through-interconnection region adjacent to the memory cell region, and
the page buffers and the memory cells are connected through a through-via extending through the first structure in the through-interconnection region.
